(19) United States
(12) Patent Application Publication
(10) Pub. No.: US 2022/0077840 A1
(43) Pub. Date: Mar. 10, 2022

(54) MULTI-LAYER PIEZOELECTRIC SUBSTRATE WITH CONTROLLABLE DELTA TEMPERATURE COEFFICIENT OF FREQUENCY

(71) Applicant: SKYWORKS SOLUTIONS, INC., Irvine, CA (US)

(72) Inventor: Joshua James Caron, Madison, NC (US)

(21) Appl. No.: 17/462,258

(22) Filed: Aug. 31, 2021

Related U.S. Application Data
(60) Provisional application No. 63/074,540, filed on Sep. 4, 2020.

(51) Int. Cl. H03H 9/02; H03H 9/25; H03H 9/64; H03H 9/145

(52) U.S. Cl. CPC H03H 9/02834; H03H 9/145; H03H 9/6483; H03H 9/25

(57) ABSTRACT

An electronic device includes a multi-layer piezoelectric substrate including a carrier substrate, a layer of piezoelectric material disposed on a front side of the carrier substrate, and a back-side layer of material disposed on a rear side of the carrier substrate, the back-side layer of material having a coefficient of thermal expansion different than a coefficient of thermal expansion of the carrier substrate, and one or more acoustic wave devices disposed on a front side of the multi-layer piezoelectric substrate, the one or more acoustic wave devices exhibiting a lesser difference in temperature coefficient of frequency at respective resonant and antiresonant frequencies than in a substantially similar device lacking the back-side layer of material.

### CROSS-REFERENCE TO RELATED APPLICATIONS

This application claims priority under 35 U.S.C. § 119(e) to U.S. Provisional Patent Application Ser. No. 63/074,540, titled MULTI-LAYER PIEZOELECTRIC SUBSTRATE WITH CONTROLLABLE DELTA TEMPERATURE COEFFICIENT OF FREQUENCY, filed Sep. 4, 2020, which is incorporated herein by reference in its entirety for all purposes.

### BACKGROUND

### Technical Field

Embodiments of this disclosure relate to acoustic wave devices and filters and to methods and structures for controlling a temperature coefficient of bandwidth in same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front end of a mobile telephone can include acoustic wave filters. Two acoustic wave filters can be arranged as a duplexer or a diplexer.

### SUMMARY

In accordance with one aspect, there is provide an electronic device. The electronic device comprises a multi-layer piezoelectric substrate including a carrier substrate, a layer of piezoelectric material disposed on a front side of the carrier substrate, and a back-side layer of material disposed on a rear side of the carrier substrate, the back-side layer of material having a coefficient of thermal expansion different than a coefficient of thermal expansion of the carrier substrate, and one or more acoustic wave devices disposed on a front side of the multi-layer piezoelectric substrate, the one or more acoustic wave devices exhibiting a lesser difference in temperature coefficient of frequency at respective resonant and antiresonant frequencies than in a substantially similar device lacking the back-side layer of material.

In some embodiments, the one or more acoustic wave devices are included in an acoustic wave filter.

In some embodiments, the one or more acoustic wave devices form a radio frequency filter.

In some embodiments, the filter has a near-zero temperature coefficient of bandwidth.

In some embodiments, the temperature coefficient of frequency at the resonant frequency of the one or more acoustic wave devices is substantially equal to the temperature coefficient of frequency at the antiresonant frequency of the one or more acoustic wave devices.

In some embodiments, the one or more acoustic wave devices are surface acoustic wave devices. The one or more acoustic wave devices may be temperature compensated surface acoustic wave devices.

In some embodiments, the one or more acoustic wave devices are bulk acoustic wave devices.

In some embodiments, the back-side layer of material has a higher temperature coefficient of frequency than the temperature coefficient of frequency of the carrier substrate.

In some embodiments, the back-side layer of material has a lower temperature coefficient of frequency than the temperature coefficient of frequency of the carrier substrate.

In some embodiments, the back-side layer of material comprises one of a dielectric or a metal.

In some embodiments, the back-side layer of material comprises a piezoelectric material.

In some embodiments, both the back-side layer of material and the layer of piezoelectric material comprise a same piezoelectric material.

In some embodiments, the back-side layer of material and the layer of piezoelectric material have substantially a same thickness.

In some embodiments, the one or more acoustic wave devices have a near-zero delta temperature coefficient of frequency.

In some embodiments, the electronic device is included in a radio frequency device module.

In some embodiments, the radio frequency device module is included in a radio frequency device.

In accordance with another aspect, there is provided a method of forming an electronic device. The method comprises forming a layer of piezoelectric material on a top surface of a carrier substrate, forming a back-side layer of material on a bottom surface of the carrier substrate, the back-side layer of material having a different coefficient of thermal expansion than a coefficient of thermal expansion of the carrier substrate, and forming one or more acoustic wave devices including portions of the layer of piezoelectric material, the back-side layer of material causing the one or more acoustic wave devices to exhibit a near-zero difference in temperature coefficient of frequency at respective resonant and antiresonant frequencies.

In some embodiments, the method further comprises forming a radio frequency filter from the one or more acoustic wave devices.

In some embodiments, the method further comprises forming a radio frequency device module including the radio frequency filter.

In some embodiments, the method further comprises forming a radio frequency electronic device including the radio frequency device.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of a temperature compensated surface acoustic wave resonator having a multi-layer piezoelectric substrate;

FIG. 3 is a simplified cross-sectional diagram of a film bulk acoustic wave resonator;

FIG. 4 is a simplified cross-sectional diagram of a Lamb wave resonator;

FIG. 5 is a simplified cross-sectional diagram of a solidly mounted resonator;

FIG. 6 is a schematic diagram of a radio frequency ladder filter;

FIG. 7 illustrates an example of a multi-layer piezoelectric substrate for an acoustic wave device;

FIG. 8 illustrates strain in multi-layer piezoelectric substrates with different back-side layers at operating temperature;

FIG. 9 is a block diagram of one example of a filter module that can include one or more electronic devices according to aspects of the present disclosure;

FIG. 10 is a block diagram of one example of a front-end module that can include one or more filter modules according to aspects of the present disclosure; and

FIG. 11 is a block diagram of one example of a wireless device including the front-end module of FIG. 10.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

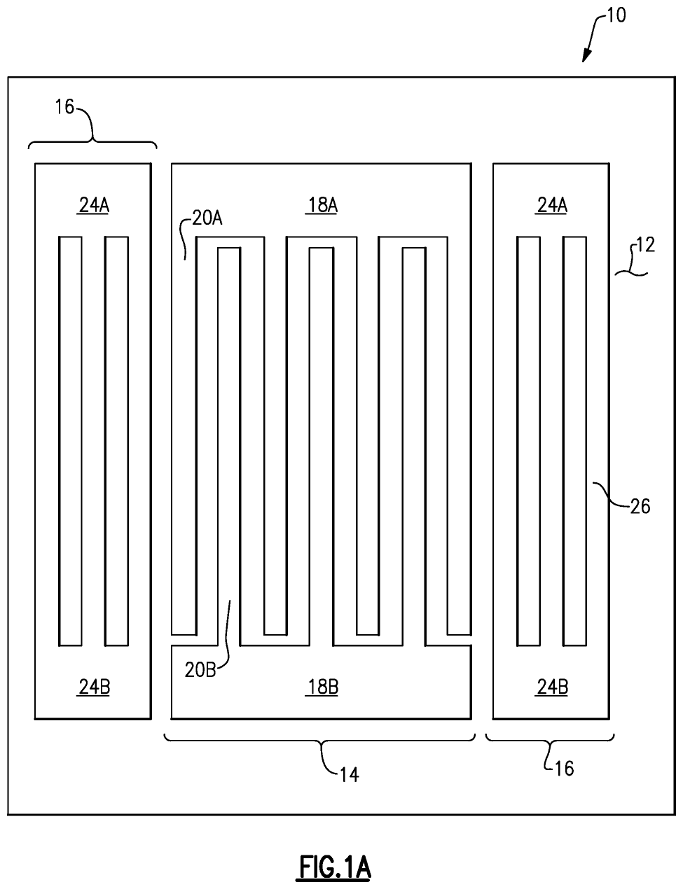

FIG. 1A is a plan view of a surface acoustic wave (SAW) resonator 10 such as might be used in a SAW filter, duplexer, diplexer, balun, etc.

Acoustic wave resonator 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing first bus bar electrode 18A. The bus bar electrodes 18A, 18B may be referred to herein together as busbar electrode 18. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B (collectively referred to herein as reflector bus bar electrode 24) and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

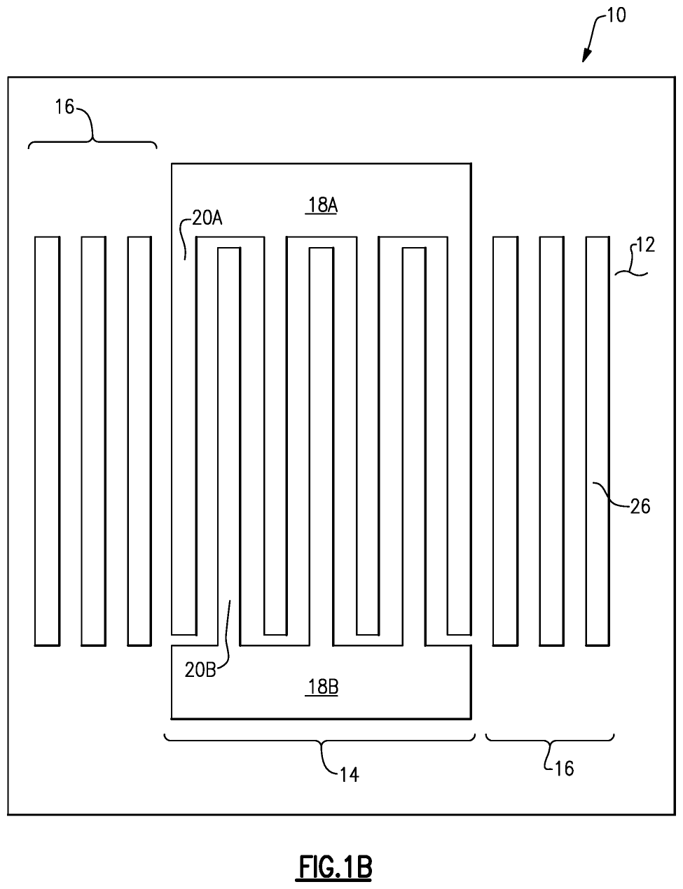

FIG. 2 is a partial cross-sectional view of a portion of the acoustic wave resonator 10 of any of FIGS. 1A-1C illustrating a few of the IDT electrodes 14 disposed on the substrate 12. In some embodiments, an acoustic wave resonator may include a multilayer piezoelectric substrate including the piezoelectric substrate 12 and a carrier substrate 22 on which the piezoelectric substrate is disposed. The carrier substrate 22 may be formed of, for example, silicon or a dielectric material, for example, silicon dioxide, aluminum oxide, or sapphire. The carrier substrate 22 is typically thicker than the piezoelectric substrate 12 and provides the acoustic wave resonator with increased mechanical strength.

The IDT electrodes 14 are formed of a metal or metal alloy, for example, aluminum. In some embodiments the IDT electrodes 14 may include multiple layers of different metals, for example, molybdenum and aluminum. A dielectric material 24, for example, silicon dioxide (SiO₂) may be disposed on top of the IDT electrodes 14 and substrate 12. The dielectric material may advantageously decrease the effect of changes in temperature upon operating characteristics of the acoustic wave resonator 10 and may protect the IDT electrodes 14 and surface of the substrate 12. For example, SiO₂ has a negative coefficient of thermal expansion while materials typically used for the piezoelectric substrate 12 in a SAW device have a positive coefficient of thermal expansion. The layer of SiO₂ 24 may thus oppose changes in dimensions of piezoelectric substrate 12 with changes in temperature that might otherwise occur in the absence of the layer of SiO₂ 24. SAW devices including a layer of SiO₂ as illustrated in FIG. 2 may be referred to as temperature-compensated SAW devices, often abbreviated as TC-SAW devices.

Aspects and embodiments disclosed herein may also be applicable to bulk acoustic wave (BAW) resonators. Film bulk acoustic wave resonators (FBAR), Lamb wave resonators, and solidly mounted resonators are examples of BAW resonators.

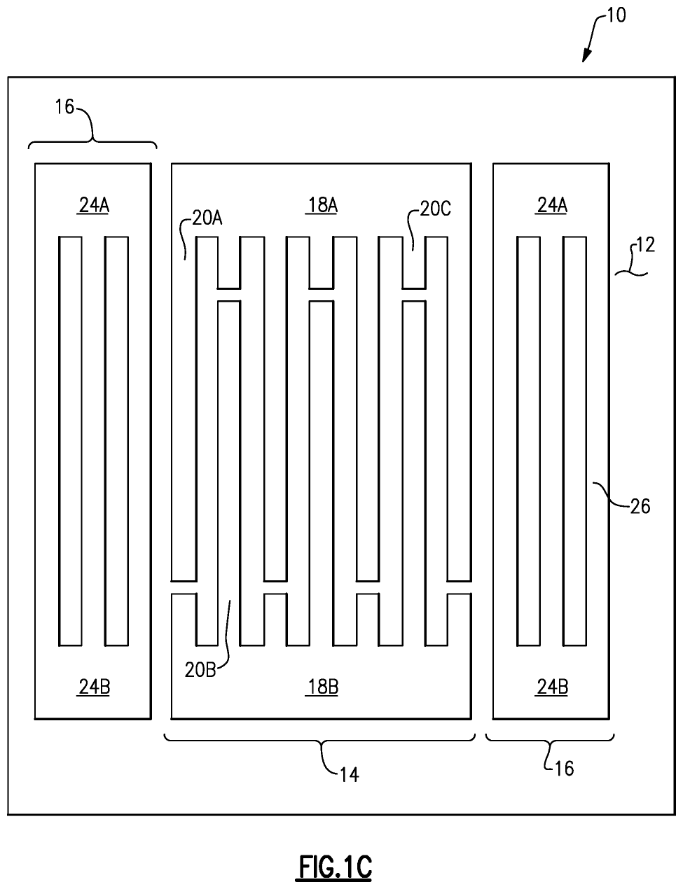

FIG. 3 is a simplified cross-sectional view of a film bulk acoustic wave resonator (FBAR) 30. The FBAR 30 includes a piezoelectric material layer 32, an upper electrode 34 on an upper surface of the piezoelectric material layer 32, and a lower electrode 36 on a lower surface of the piezoelectric material layer 32. The piezoelectric material layer 32 can be a thin film. The piezoelectric material layer 32 can be an aluminum nitride layer. In other instances, the piezoelectric material layer 32 can be any suitable piezoelectric material layer. The piezoelectric material layer 32 is disposed on a substrate 39 and defines a cavity 38 between a lower surface of the piezoelectric material layer 32 and the substrate 39. The lower electrode 36 is disposed in the cavity 38. The cavity 38 may be filled with air or another gas, or in other embodiments may be evacuated to form a vacuum cavity.

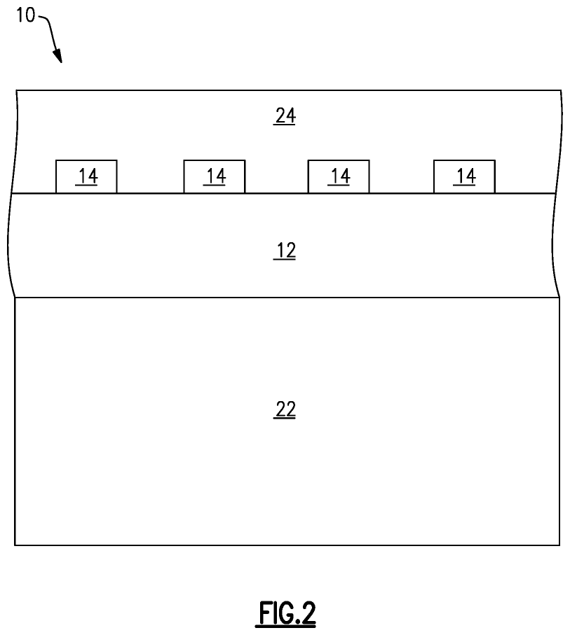

FIG. 4 is a simplified cross-sectional view of a Lamb wave resonator 40. The Lamb wave resonator 40 includes features of a SAW resonator and an FBAR. As illustrated, the Lamb wave resonator 40 includes a piezoelectric material layer 42, an interdigital transducer electrode (IDT) 44 on an upper surface of the piezoelectric material layer 42, and a lower electrode 46 disposed on a lower surface of the piezoelectric material layer 42. The piezoelectric material layer 42 can be a thin film. The piezoelectric material layer 42 can be an aluminum nitride layer. In other instances, the piezoelectric material layer 42 can be any suitable piezoelectric layer. The frequency of the Lamb wave resonator can be based on the geometry of the IDT 44. The electrode 46 can be grounded in certain instances. In some other instances, the electrode 46 can be floating. An air cavity 48 is disposed between the electrode 46 and a substrate 49. Any suitable cavity can be implemented in place of the air cavity 48, for example, a vacuum cavity or a cavity filled with a different gas.

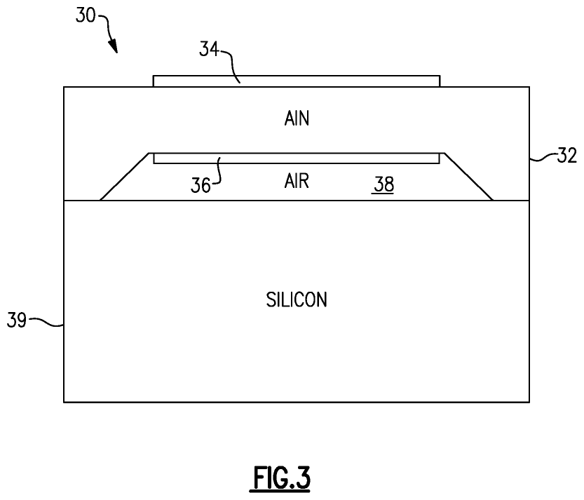

FIG. 5 is a simplified cross-sectional view of a solidly mounted resonator (SMR) 50. As illustrated, the SMR 50 includes a piezoelectric material layer 52, an upper electrode 54 disposed on top of the piezoelectric material layer 52, and a lower electrode 56 disposed on a lower surface of the piezoelectric material layer 52. The piezoelectric material layer 52 can be an aluminum nitride layer. In other instances, the piezoelectric material layer 52 can be any other suitable piezoelectric material layer. The lower electrode 56 can be grounded in certain instances. In some other instances, the lower electrode 56 can be floating. Bragg reflectors 58 are disposed between the lower electrode 56 and a semiconductor substrate 59. Any suitable Bragg reflectors can be implemented. For example, the Bragg reflectors can be SiO₂/W.

The substrates 39, 49, 59 in FIGS. 3-5 are indicated as being silicon, but may alternatively be formed of another material, for example, a dielectric material such as silicon dioxide, aluminum oxide, or sapphire.

It should be appreciated that the acoustic wave resonators illustrated in FIGS. 1A-5, as well as those illustrated in other figures presented herein, are illustrated in a highly simplified form. The relative dimensions of the different features are not shown to scale. For example, typical surface acoustic wave resonators would commonly include a far greater number of electrode fingers and/or reflector fingers than illustrated. The acoustic wave resonators may be configured differently than illustrated in some examples, for example, in some embodiments surface acoustic wave resonators may include dummy electrode fingers, electrode fingers with different or non-uniform length or width dimensions, electrode fingers or reflector fingers with different or non-uniform spacing, or electrode fingers that include bent or tilted portions. Typical surface acoustic wave resonators or filter elements may also include multiple IDT electrodes sandwiched between the reflector electrodes.

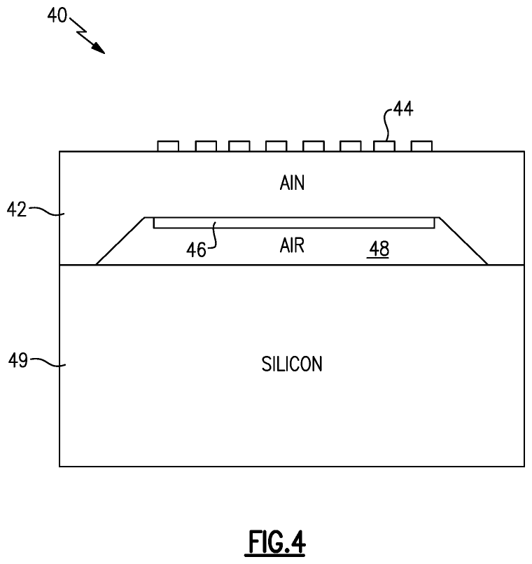

Acoustic wave resonators as disclosed herein may be electrically coupled to form an acoustic wave filter, for example a radio frequency (RF) acoustic wave filter. One example of a filter architecture is a ladder filter. An example of an RF ladder filter schematically illustrated in FIG. 6. The RF ladder filter includes a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include acoustic wave devices or resonators, for example, duplexers, baluns, etc., may also be formed including examples of the acoustic wave resonators as disclosed herein.

Acoustic wave resonators often have a different temperature coefficient of frequency (TCF) at the resonant frequency (fᵣ) than at the anti-resonant frequency (fₐ). This difference in TCF will be referred to herein as delta TCF (ΔTCF). It is typically measured in ppm/° C. Since the frequency separation between fᵣ and fₐ is largely responsible for determining the bandwidth in a filter formed of acoustic wave resonators, ΔTCF can be considered as a temperature coefficient of bandwidth for a filter formed of acoustic wave resonators. Furthermore, varying separation between fᵣ and fₐ also causes a change in filter impedance, potentially causing degradation in the voltage standing wave ratio (VSWR) or impacting the interactions between the filter and other adjacent RF components in an RF system (for example, power amplifiers or low noise amplifiers). In acoustic wave filters including multilayer piezoelectric substrate (MPS) acoustic wave resonators, the ΔTCF value can be especially large and problematic. It would be desirable to provide acoustic wave resonators and filters with low or zero ΔTCF values so that the operating characteristics, for example, resonant and antiresonant frequencies or bandwidth of the resonators or filters are not significantly impacted by with changes in operating temperature.

A major contributor to ΔTCF in MPS resonators and filters formed therefrom (MPS filters) is temperature-dependent stress in the piezoelectric material film of the MPS resonators. The temperature-dependent stress may be induced by a mismatch in the coefficient of thermal expansion (CTE) between the piezoelectric material film and the underlying carrier substrate, for example, between piezoelectric material film 12 and carrier substrate 22 in FIG. 2 or between the piezoelectric material films 32, 42, 52 and respective carrier substrates 39, 49, 59 in FIGS. 3-5.

Aspects and embodiments disclosed herein include MPS acoustic wave resonators and filters with a near-zero ΔTCF, for example, within a range of ±2 ppm/° C. The resonators of an MPS filter may include a back-side layer with a CTE that is different from the CTE of the main carrier substrate. The CTE mismatch between the main carrier substrate and the back-side layer induces strain in the acoustic wave resonators, causing the carrier substrate to bow in an upward (convex) or downward (concave) fashion, depending on whether the CTE of the back-side layer is less than or greater than that of the main carrier substrate, respectively. The convex or concave strain caused by the back-side layer imparts tensile or compressive stress, respectively, in the piezoelectric film on the front (top) side of the resonator. Any change in temperature causes a proportional change in stress. The direction of the induced stress (tensile or compressive) is determined by the magnitude of the CTE of the back-side layer compared to that of the main carrier substrate, and the sensitivity of the change is determined by the degree of CTE mismatch, the Young's moduli of the carrier substrate and back-side materials, and the relative thickness of the back-side layer and carrier substrate. Since film thickness can be controlled quite easily using modern fabrication technologies, this provides a very simple degree of freedom for producing acoustic wave resonators or having a zero or near-zero ΔTCF.

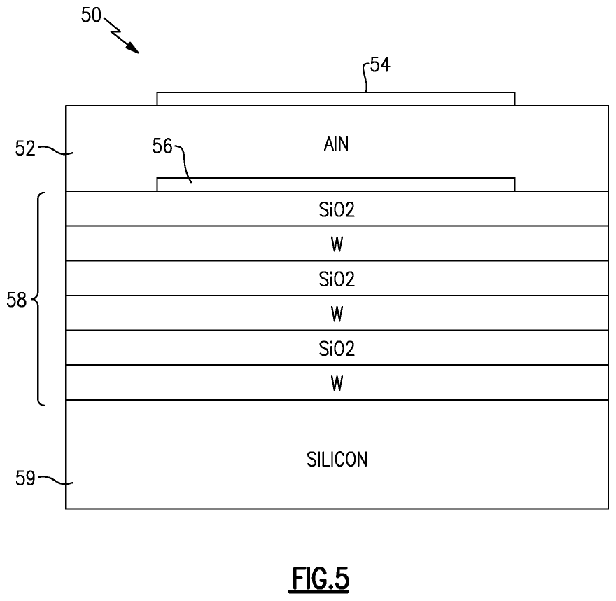

FIG. 7 schematically illustrates a cross-section of the material layers in an acoustic wave resonator 700 having a zero or near-zero ΔTCF as disclosed herein. The acoustic wave resonator includes a layer of piezoelectric material 705 that may be structured or may include any of the electrodes or other features of the acoustic wave resonators illustrated in FIGS. 1A-5 or of other acoustic wave resonators known in the art on or within the layer of piezoelectric material 705 and may be wholly or partially covered by one or more overlying dielectric layers, for example, as illustrated in FIG. 2. The piezoelectric material layer 705 is disposed on the front or upper surface of a carrier substrate 710, which may correspond to the carrier substrates 22, 39, 49, or 59 of any of the acoustic wave resonators illustrated in FIGS. 1A-5 or of other acoustic wave resonators known in the art. A back-side layer 715 that has a CTE different from that of the carrier substrate 710 is disposed on a rear or lower side of the carrier substrate 710 opposite the front side of the carrier substrate 710 upon which the layer of piezoelectric material 705 is disposed. The back-side layer may be formed of one or more layers of material and may include layers of different materials. In some embodiments the back-side layer 715 has a higher CTE than the carrier substrate 710. If the carrier substrate 710 is formed of, for example, silicon, with a CTE of about 2.6 ppm/° C., the back-side layer may be formed of one or more of a piezoelectric material, for example, lithium niobate (CTE of about 7.5 ppm/° C. to about 15.4 ppm/° C. depending on crystallographic orientation), lithium tantalate (CTE of about 2 ppm/° C. to about 16 ppm/° C. depending on crystallographic orientation), or aluminum nitride (CTE of about 4.6 ppm/° C.), a dielectric, for example, aluminum oxide (CTE of about 4.5 ppm/° C.) sapphire (CTE of about 5.3 ppm/° C.), or silicon carbide (CTE of about 2.8 ppm/° C.) or a metal, for example, copper (CTE of about 17 ppm/° C.) or aluminum (CTE of about 23 ppm/° C.). In some embodiments, the back-side layer 715 may be formed of the same material and with substantially the same thickness as the piezoelectric material layer 705. In other embodiments the back-side layer 715 has a lower CTE than the carrier substrate 710. If the carrier substrate 710 is formed of, for example, silicon, with a CTE of about 2.6 ppm/° C., the back-side layer may be formed of one or more of silicon nitride (CTE of about 1.4 ppm/° C.), diamond (CTE of about 1 ppm/° C.), or silicon dioxide (CTE of about 0.65 ppm/° C.). In some embodiments, the back-side layer may be formed of or include copper or SiN in a thickness range of between 1% and 20% the thickness of the main carrier substrate. For a carrier substrate with a thickness in the range of 50-250 um, the range of back-side layer thickness may be, for example, between 0.5 um and 50 um.

The back-side layer 715 may be deposited directly on the rear or lower side of the carrier substrate 710 using an appropriate chemical vapor deposition or physical vapor deposition process (e.g., evaporation deposition or sputtering). In other embodiments, the back-side layer 715 may be adhered to the rear or lower side of the carrier substrate 710 using an appropriate adhesion layer, for example, one or more of silicon dioxide, chromium, platinum, titanium, titanium dioxide, gold, or any other appropriate dielectric or metallic adhesion layer material. In other embodiments, a metallic back-side layer may be created by electroplating.

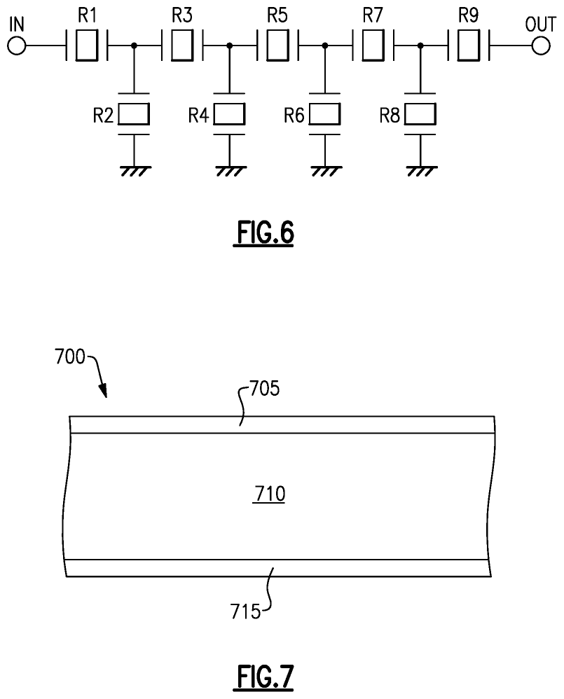

As illustrated in FIG. 8, the CTE mismatch between the main carrier substrate and the back-side layer induces strain in the device, causing the substrate to bow in an upward (convex) or downward (concave) fashion, depending on whether the CTE of the back-side layer is less than or greater than that of the main carrier substrate, respectively. The convex or concave strain caused by the back-side layer imparts tensile or compressive stress, respectively, in the thin piezoelectric film on the front (top) side of the device. A change in temperature causes a proportional change in stress. The direction of the induced stress (tensile or compressive) is determined by the magnitude of the CTE of the back-side layer CTE compared to that of the main carrier substrate, and the sensitivity of the change is determined by the degree of CTE mismatch, the elastic moduli of the carrier substrate and back-side materials, and the relative thickness of the back-side layer as compared to the carrier substrate, and, to a lesser degree, the composition and thickness of the piezoelectric material layer. Since the film thickness of the back-side layer can be readily and accurately controlled using modern film deposition processes, this provides an easily controllable method for providing an acoustic wave resonator or filter as disclosed herein with a zero or near-zero ΔTCF.

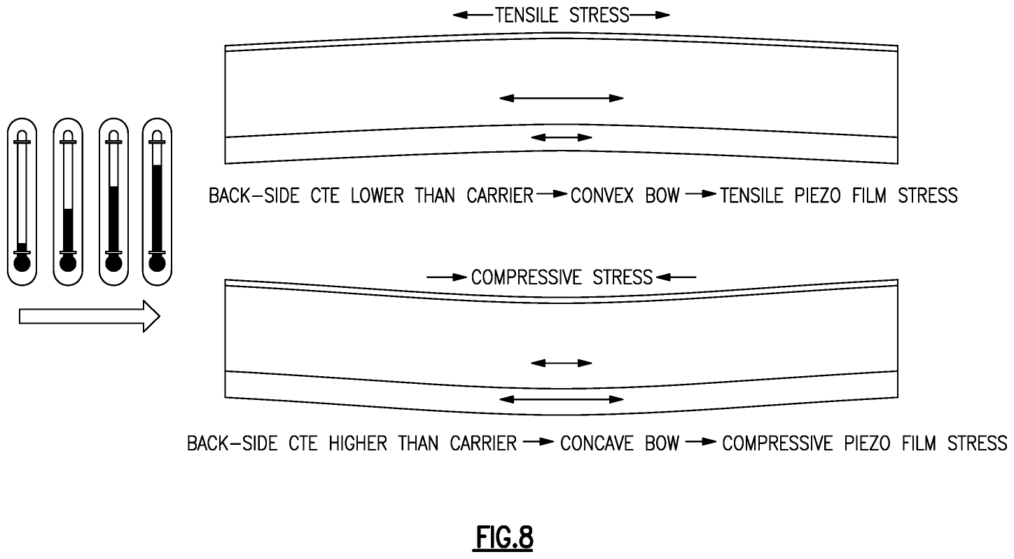

As discussed above, embodiments of the acoustic wave elements disclosed herein can be configured as or used in filters, for example. Embodiments of the acoustic wave elements disclosed herein can be configured as, for example, a ladder filter having a structure and configuration as known in the art. In turn, an acoustic wave filter using one or more acoustic wave elements may be incorporated into and packaged as a module that may ultimately be used in an electronic device, such as a wireless communications device, for example. FIG. 9 is a block diagram illustrating one example of a module 800 including an acoustic wave filter 810. The filter 810 may be implemented on one or more die(s) 820 including one or more connection pads 822. For example, the filter 810 may include a connection pad 822 that corresponds to an input contact for the filter and another connection pad 822 that corresponds to an output contact for the filter. The packaged module 800 includes a packaging substrate 830 that is configured to receive a plurality of components, including the die 820. A plurality of connection pads 832 can be disposed on the packaging substrate 830, and the various connection pads 822 of the filter die 820 can be connected to the connection pads 832 on the packaging substrate 830 via electrical connectors 834, which can be solder bumps or wirebonds, for example, to allow for passing of various signals to and from the filter 810. The module 800 may optionally further include other circuitry die 840, such as, for example one or more additional filter(s), amplifiers, switches, pre-filters, modulators, demodulators, down converters, and the like, as would be known to one of skill in the art of semiconductor fabrication in view of the disclosure herein. In some embodiments, the module 800 can also include one or more packaging structures to, for example, provide protection and facilitate easier handling of the module 800. Such a packaging structure can include an overmold formed over the packaging substrate 830 and dimensioned to substantially encapsulate the various circuits and components thereon.

Various examples and embodiments of the filter 810 can be used in a wide variety of electronic devices. For example, the filter 810 can be used in an antenna duplexer, which itself can be incorporated into a variety of electronic devices, such as RF front-end modules and communication devices.

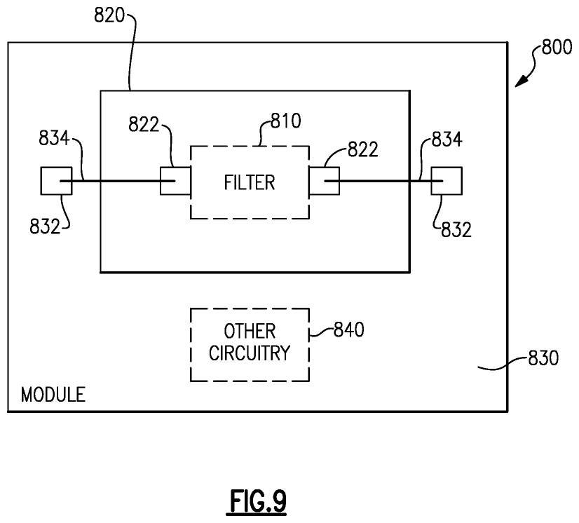

Referring to FIG. 10, there is illustrated a block diagram of one example of a front-end module 900, which may be used in an electronic device such as a wireless communications device (e.g., a mobile phone) for example. The front-end module 900 includes an antenna duplexer 910 having a common node 902, an input node 904, and an output node 906. An antenna 1010 is connected to the common node 902.

The antenna duplexer 910 may include one or more transmission filters 912 connected between the input node 904 and the common node 902, and one or more reception filters 914 connected between the common node 902 and the output node 906. The passband(s) of the transmission filter(s) are different from the passband(s) of the reception filters. Examples of the filter 810 can be used to form the transmission filter(s) 912 and/or the reception filter(s) 914. An inductor or other matching or phasing component 920 may be connected at the common node 902.

The front-end module 900 further includes a transmitter circuit 932 connected to the input node 904 of the duplexer 910 and a receiver circuit 934 connected to the output node 906 of the duplexer 910. The transmitter circuit 932 can generate signals for transmission via the antenna 1010, and the receiver circuit 934 can receive and process signals received via the antenna 1010. In some embodiments, the receiver and transmitter circuits are implemented as separate components, as shown in FIG. 10, however in other embodiments these components may be integrated into a common transceiver circuit or module. As will be appreciated by those skilled in the art, the front-end module 900 may include other components that are not illustrated in FIG. 10 including, but not limited to, switches, electromagnetic couplers, amplifiers, processors, and the like.

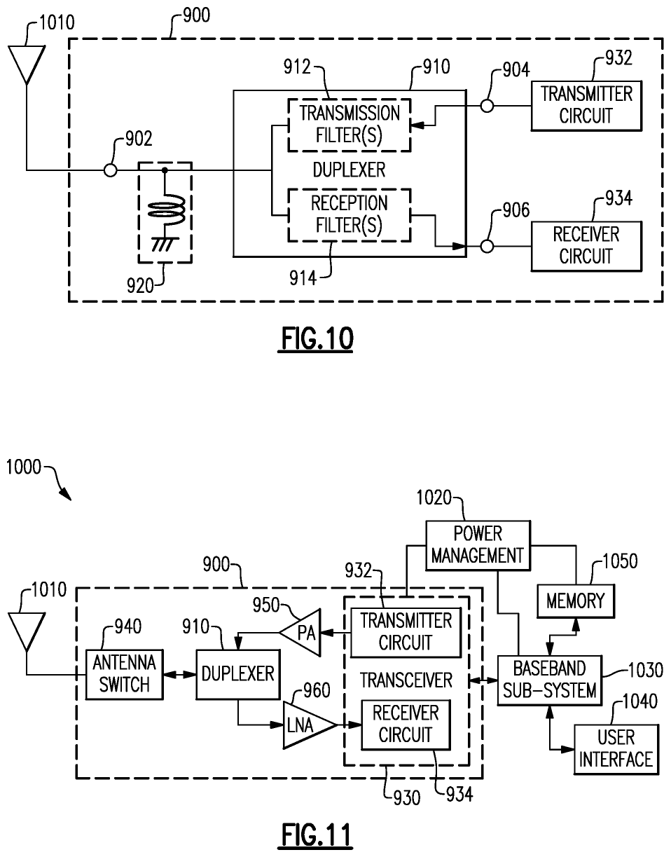

FIG. 11 is a block diagram of one example of a wireless device 1000 including the antenna duplexer 910 shown in FIG. 10. The wireless device 1000 can be a cellular phone, smart phone, tablet, modem, communication network or any other portable or non-portable device configured for voice or data communication. The wireless device 1000 can receive and transmit signals from the antenna 1010. The wireless device includes an embodiment of a front-end module 900 similar to that discussed above with reference to FIG. 10. The front-end module 900 includes the duplexer 910, as discussed above. In the example shown in FIG. 11 the front-end module 900 further includes an antenna switch 940, which can be configured to switch between different frequency bands or modes, such as transmit and receive modes, for example. In the example illustrated in FIG. 11, the antenna switch 940 is positioned between the duplexer 910 and the antenna 1010; however, in other examples the duplexer 910 can be positioned between the antenna switch 940 and the antenna 1010. In other examples the antenna switch 940 and the duplexer 910 can be integrated into a single component.

The front-end module 900 includes a transceiver 930 that is configured to generate signals for transmission or to process received signals. The transceiver 930 can include the transmitter circuit 932, which can be connected to the input node 904 of the duplexer 910, and the receiver circuit 934, which can be connected to the output node 906 of the duplexer 910, as shown in the example of FIG. 10.

Signals generated for transmission by the transmitter circuit 932 are received by a power amplifier (PA) module 950, which amplifies the generated signals from the transceiver 930. The power amplifier module 950 can include one or more power amplifiers. The power amplifier module 950 can be used to amplify a wide variety of RF or other frequency-band transmission signals. For example, the power amplifier module 950 can receive an enable signal that can be used to pulse the output of the power amplifier to aid in transmitting a wireless local area network (WLAN) signal or any other suitable pulsed signal. The power amplifier module 950 can be configured to amplify any of a variety of types of signal, including, for example, a Global System for Mobile (GSM) signal, a code division multiple access (CDMA) signal, a W-CDMA signal, a Long-Term Evolution (LTE) signal, a New Radio (NR) signal, or an EDGE signal. In certain embodiments, the power amplifier module 950 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 11, the front-end module 900 may further include a low noise amplifier module 960, which amplifies received signals from the antenna 1010 and provides the amplified signals to the receiver circuit 934 of the transceiver 930.

The wireless device 1000 of FIG. 11 further includes a power management sub-system 1020 that is connected to the transceiver 930 and manages the power for the operation of the wireless device 1000. The power management system 1020 can also control the operation of a baseband sub-system 1030 and various other components of the wireless device 1000. The power management system 1020 can include, or can be connected to, a battery (not shown) that supplies power for the various components of the wireless device 1000. The power management system 1020 can further include one or more processors or controllers that can control the transmission of signals, for example. In one embodiment, the baseband sub-system 1030 is connected to a user interface 1040 to facilitate various input and output of voice and/or data provided to and received from the user. The baseband sub-system 1030 can also be connected to memory 1050 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An electronic device comprising:
a multi-layer piezoelectric substrate including a carrier substrate, a layer of piezoelectric material disposed on a front side of the carrier substrate, and a back-side layer of material disposed on a rear side of the carrier substrate, the back-side layer of material having a coefficient of thermal expansion different than a coefficient of thermal expansion of the carrier substrate; and
one or more acoustic wave devices disposed on a front side of the multi-layer piezoelectric substrate, the one or more acoustic wave devices exhibiting a lesser difference in temperature coefficient of frequency at respective resonant and antiresonant frequencies than in a substantially similar device lacking the back-side layer of material.

2. The electronic device of claim 1 wherein the one or more acoustic wave devices are included in an acoustic wave filter.

3. The electronic device of claim 1 wherein the one or more acoustic wave devices form a radio frequency filter.

4. The electronic device of one of claim 2 wherein the filter has a near-zero temperature coefficient of bandwidth.

5. The electronic device of claim 1 wherein the temperature coefficient of frequency at the resonant frequency of the one or more acoustic wave devices is substantially equal to the temperature coefficient of frequency at the antiresonant frequency of the one or more acoustic wave devices.

6. The electronic device of claim 1 wherein the one or more acoustic wave devices are surface acoustic wave devices.

7. The electronic device of claim 6 wherein the one or more acoustic wave devices are temperature compensated surface acoustic wave devices.

8. The electronic device of claim 1 wherein the one or more acoustic wave devices are bulk acoustic wave devices.

9. The electronic device of claim 1 wherein the back-side layer of material has a higher temperature coefficient of frequency than the temperature coefficient of frequency of the carrier substrate.

10. The electronic device of claim 1 wherein the back-side layer of material has a lower temperature coefficient of frequency than the temperature coefficient of frequency of the carrier substrate.

11. The electronic device of claim 1 wherein the back-side layer of material comprises one of a dielectric or a metal.

12. The electronic device of claim 1 wherein the back-side layer of material comprises a piezoelectric material.

13. The electronic device of claim 12 wherein both the back-side layer of material and the layer of piezoelectric material comprise a same piezoelectric material.

14. The electronic device of claim 13 wherein the back-side layer of material and the layer of piezoelectric material have substantially a same thickness.

15. The electronic device of claim 1 wherein the one or more acoustic wave devices have a near-zero delta temperature coefficient of frequency.

16. A radio frequency device module including the electronic device of claim 1.

17. A radio frequency device including the radio frequency module of claim 15.

18. A method of forming an electronic device, the method comprising:
forming a layer of piezoelectric material on a top surface of a carrier substrate;
forming a back-side layer of material on a bottom surface of the carrier substrate, the back-side layer of material having a different coefficient of thermal expansion than a coefficient of thermal expansion of the carrier substrate; and
forming one or more acoustic wave devices including portions of the layer of piezoelectric material, the back-side layer of material causing the one or more acoustic wave devices to exhibit a near-zero difference in temperature coefficient of frequency at respective resonant and antiresonant frequencies.

19. The method of claim 18 further comprising forming a radio frequency filter from the one or more acoustic wave devices.

20. The method of claim 18 further comprising forming a radio frequency device module including the radio frequency filter of claim 19.

21. The method of claim 20 further comprising forming a radio frequency electronic device including the radio frequency device module of claim 20.
